(19) United States
(12) Patent Application Publication
(10) Pub. No.: US 2010/0072484 A1
(43) Pub. Date: Mar. 25, 2010

(54) HETEROEPITAXIAL GALLIUM NITRIDE-BASED DEVICE FORMED ON AN OFF-CUT SUBSTRATE

(75) Inventors: Jose Jimenez, Dallas, TX (US); Uttiya Chowdhury, Plano, TX (US)

Correspondence Address: Schwabe Williamson & Wyatt;PACWEST CENTER, SUITE 1900, 1211 SW FIFTH AVENUE, PORTLAND, OR, 97204, US

(73) Assignee: TRIQUINT SEMICONDUCTOR, INC., Hillsboro, OR (US)

(21) Appl. No.: 12/236,438

(22) Filed: Sep. 23, 2008

(51) Int. Cl. H01L 29/15; H01L 21/338

(52) U.S. Cl. 257/77; 438/172; 257/E29.072; 257/E21.45

(57) ABSTRACT

Embodiments include but are not limited to apparatuses and systems including a heteroepitaxial gallium nitride-based device formed on an off-cut substrate, and methods for making the same. Other embodiments may be described and claimed.

### TECHNICAL FIELD

Embodiments of the present invention relate generally to microelectronic devices and more particularly to heteroepitaxial gallium nitride-based devices formed on off-cut substrates.

### BACKGROUND

Gallium nitride (GaN) heterojunction field effect transistors (HFET) have a number of applications including devices operated at high power and high frequency. Conventionally, GaN HFET devices are formed on “on-cut” substrates in which the atomic planes of a substrate are oriented parallel to the major surface of the substrate. Although these devices are promising, their full potential is limited due at least in part to current-collapse issues.

The current-collapse phenomenon is known to occur at high drain bias resulting in charges becoming trapped at the drain-gate edge of the transistor at either side of the electron channel. The trapped charges are slow to escape their deep traps, which may result in low radio frequency (RF) performance. Moreover, current collapse not only may reduce the maximum RF power available on a GaN-based HFET, but also may be a source of non-uniformity across the semiconductor wafer. Accordingly, a method for reducing current collapse, while increasing wafer uniformity, is desirable. To remedy the current collapse problem, many have resorted to simply adding or changing the passivation layer right over the semiconductor surface. Although this may result in a reduction in current collapse, further reduction may be possible.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a heterojunction field effect transistor formed on an off-cut substrate in accordance with various embodiments of the present invention.

FIG. 2a illustrates a related-art on-cut substrate, and FIG. 2b illustrates an off-cut substrate in accordance with various embodiments of the present invention.

FIG. 3 illustrates a heteroepitaxial structure including epitaxial layer(s) formed on an off-cut substrate in accordance with various embodiments of the present invention.

FIGS. 4a-4g illustrate various stages of a method for forming a heterojunction field effect transistor on an off-cut substrate in accordance with various embodiments of the present invention.

FIG. 5 illustrates a block diagram of a system incorporating a heteroepitaxial gallium nitride-based device formed on an off-cut substrate in accordance with various embodiments of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent. Moreover, some embodiments may include more or fewer operations than may be described.

The description may use the phrases “in an embodiment,” “in embodiments,” “in some embodiments,” or “in various embodiments,” which may each refer to one or more of the same or different embodiments. Furthermore, the terms “comprising,” “including,” “having,” and the like, as used with respect to embodiments of the present invention, are synonymous.

The terms “coupled to,” along with its derivatives, may be used herein. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled to each other.

The phrase “formed on,” along with its derivatives, may be used herein. “Formed on” in the context of a layer being “formed on” another layer may mean that a layer is formed above, but not necessarily in direct physical or electrical contact with, another layer (e.g., there may be one or more other layers interposing the layers). In some embodiments, however, “formed on” may mean that a layer is in direct physical contact with at least a portion of a top surface of another layer. Usage of terms like “top” and “bottom” are to assist in understanding, and they are not to be construed to be limiting on the disclosure.

For the purposes of the present invention, the phrase “A/B” means A or B. The phrase “A and/or B” means “(A), (B), or (A and B).” The phrase “at least one of A, B, and C” means “(A), (B), (C), (A and B), (A and C), (B and C), or (A, B and C).” The phrase “(A)B” means “(B) or (AB),” that is, A is an optional element.

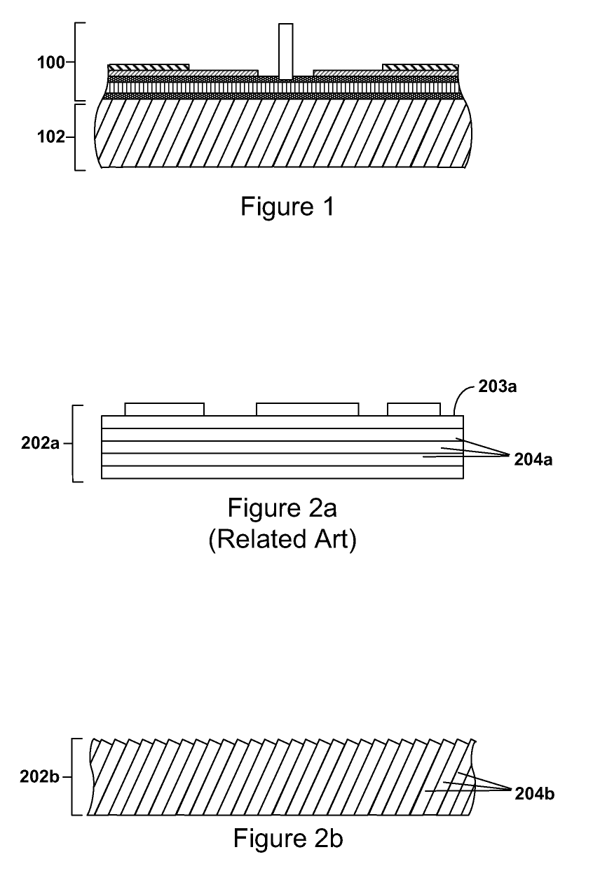

Turning now to FIG. 1, a device including a heterojunction field effect transistor (HFET) 100 formed on an off-cut substrate 102 is illustrated. Forming the HFET 100 on the off-cut substrate 102, as opposed to an on-cut substrate, may result in lower macroscopic roughness and thus decreased current collapse and increased wafer uniformity relative to HFETs formed on on-cut substrates. Depending on the particular application, this decreased current collapse may further result in increased radio frequency output power.

When referring to substrates, “off-cut,” as opposed to “on-cut,” is sometimes referred to in the art as “vicinal,” and typically means that the atomic planes of the substrate are oriented off-parallel to the major surface of the substrate. FIGS. 2a and 2b illustrate this contrast. The related-art on-cut substrate 202a of FIG. 2a includes atomic planes 204a that are parallel to the major surface 203a of the substrate 202a. Contrast this to the off-cut substrate 202b of FIG. 2b including atomic planes 204b that are at an angle relative to the major surface 203b of the substrate 202b. The atomic planes 204b of the off-cut substrate 202b form dense atomic steps across the major surface 203b of the substrate 202b, whereas the atomic planes 204a of the on-cut substrate 202a form low-density atomic steps across its major surface 203a.

The increased density of atomic steps of the off-cut substrate 202b may provide a correspondingly increased density of nucleation sites during epitaxial growth, leading to a smoother surface morphology (i.e., reduction of surface defects such as hillocks) compared to epitaxial layer(s) grown on the on-cut substrate 202a. It has been discovered that reducing the roughness of the epitaxial surface may result in a corresponding reduction in current collapse of device(s) formed from the epitaxial layer(s).

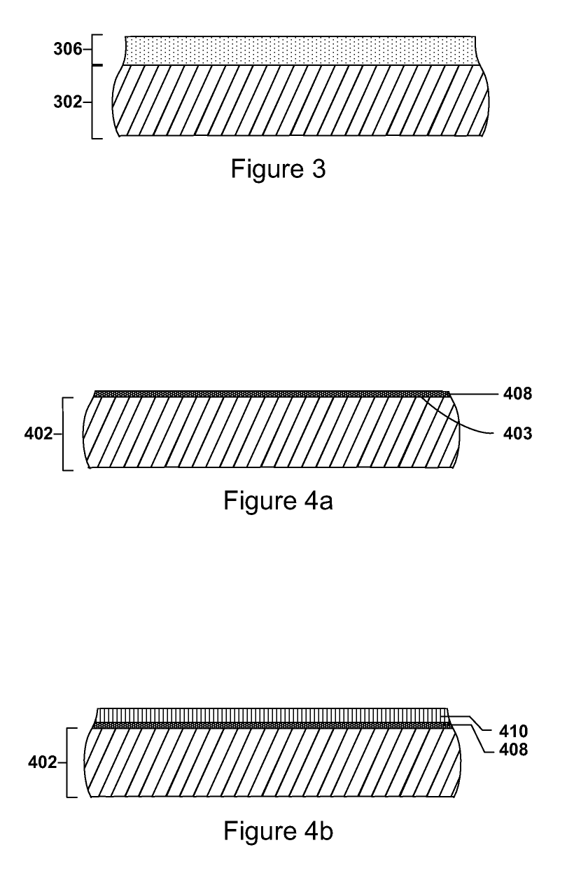

The use of off-cut substrates may result in a beneficial reduction of current collapse for various types of devices. FIG. 3 illustrates starting layers that may be used for forming one or more of these types of devices, the starting layers including an epitaxial structure 306 (formed with one or more epitaxial layers) on an off-cut substrate 302. In various embodiments, the epitaxial structure 306 is formed from material different than the material of the substrate (i.e., heteroepitaxial). The epitaxial structure 306 may comprise layers suitable for forming transistors, optoelectronic devices, and the like. For example, HFETs (sometimes referred to as high electron mobility transistors (HEMT)), diodes, light emitting devices, detectors, etc., may be formed from the epitaxial structure 306.

HFETs, such as the one illustrated in FIG. 1, for example, may find particularly beneficial current collapse reduction from using an off-cut substrate. HFETs may comprise any known type of HFET including group III-V compound epitaxial layer(s). In general, various embodiments of the present invention may be used in any heteroepitaxial gallium nitride (GaN)-based device formed from epitaxial layers that differ from the material of the substrate. For example, various electronic and optoelectronic devices (e.g., light emitting diodes) may be formed from epitaxially grown gallium nitride (GaN) on silicon carbide (SiC) substrates.

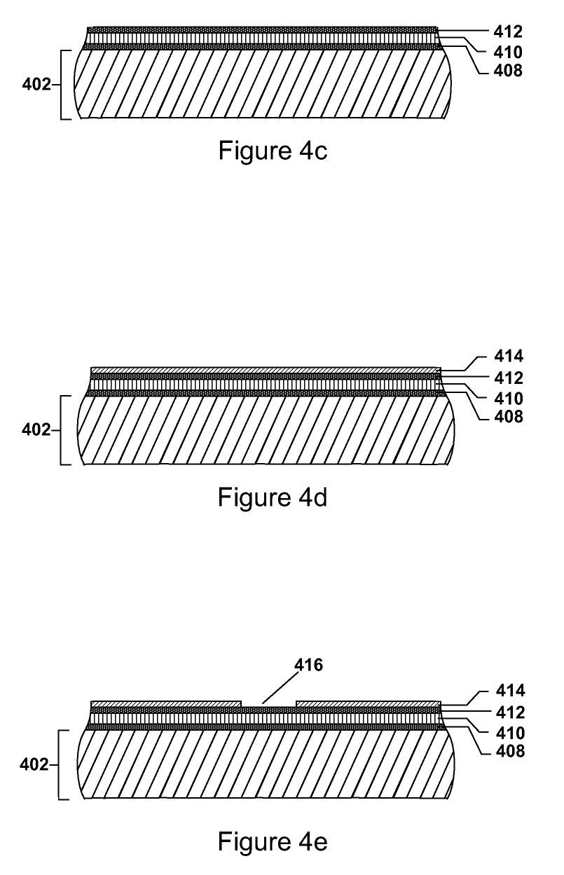

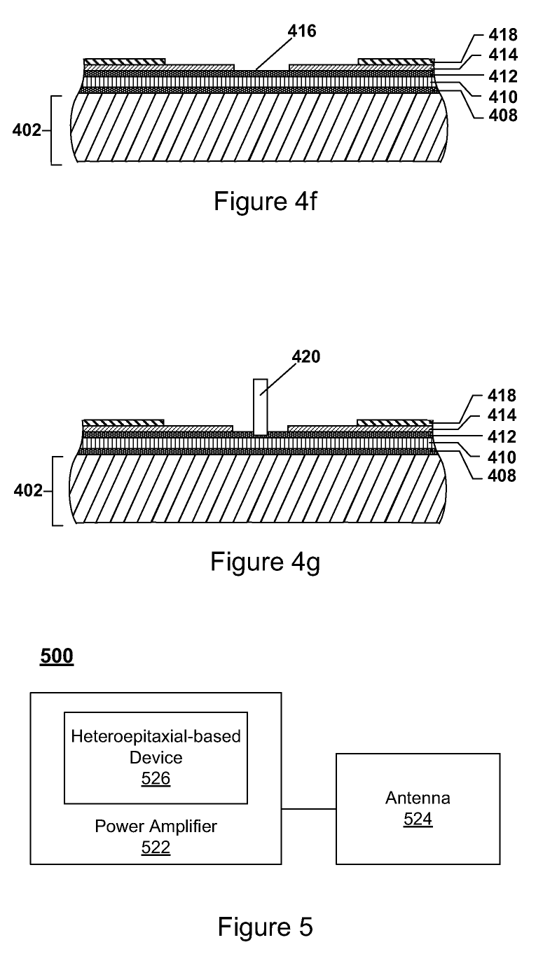

Turning now to FIGS. 4a-4g, an exemplary method for forming a device, such as, for example, the device of FIG. 1, is illustrated by way of cross-sectional side views of the device at various stages of the method. One or more operations of the illustrated method may also be suitable for making other types of devices as discussed above, including, for example, optoelectronic and other devices. It should be noted that various operations discussed and/or illustrated may be generally referred to as multiple discrete operations in turn to help in understanding embodiments of the present invention. The order of description should not be construed to imply that these operations are order dependent, unless explicitly stated. Moreover, some embodiments may include more or fewer operations than may be described.

As illustrated in FIG. 4a, an off-cut substrate 402 is provided. The substrate 402 is off-cut by some off-cut angle. Although various off-cut angles may realize a suitable increase in epitaxial layer smoothness, an off-cut angle of 0.2° or more, relative to the major surface 403 of the substrate 402, may be sufficient to eliminate the formation of surface defects. In some embodiments, an off-cut angle of 0.4° or more may be used. In some embodiments, an off-cut angle of 0.7° or less may be used.

The off-cut substrate 402 may comprise any material suitable for the application. For various embodiments, for example, the substrate 402 comprises SiC. SiC may be particularly suitable for devices having high radio frequency power and high frequency operation due at least in part to the thermal and isolation properties of SiC. In other embodiments, however, the substrate 402 may comprise silicon, sapphire, aluminum nitride, gallium nitride, or some combination thereof or some combination with another suitable material. In general, the selected substrate material need not be the same material as the material of the device layers.

A nucleation (or buffer) layer 408 may be formed on the substrate 402. The nucleation layer 408 may comprise aluminum nitride or aluminum gallium nitride. Other materials may be similarly suitable. In some embodiments, a device may be formed without the nucleation layer 408. Indeed, in various embodiments, using the off-cut substrate 402 may make use of the nucleation layer 408 unnecessary. In some embodiments, however, the nucleation layer 408 may result in further smoothing of the resulting epitaxial layer.

A GaN layer 410 may be formed on the nucleation layer 408 as illustrated in FIG. 4b. As noted above, however, in some embodiments a device may be formed without nucleation layer 408 in which case the GaN layer 410 may be formed directly onto the substrate 402. In various other embodiments, one or more of various other layers may be provided between the GaN layer 410 and the substrate 402. In some embodiments, the GaN layer 410 may be substituted with another material for forming an active layer. For example, the GaN layer 410 may be substituted with a GaN-based material (e.g., AlGaN, InGaN, AlInGaN, etc.).

The GaN layer 410 may be formed with characteristics suitable for forming various types of devices as discussed herein. For example, the GaN layer 410 may form a channel layer for an HFET device, an active layer for an optoelectronic device, and the like. The GaN layer 410 may be doped or undoped, depending on the application, for achieving desired electrical properties. Doping may be performed either in situ or after deposited.

A barrier layer 412 may be formed on the GaN (or active) layer 410 as illustrated in FIG. 4c. The barrier layer 412 may comprise aluminum gallium nitride. Another material or combination of materials may be similarly suitable. For example, the barrier layer 412 may comprise indium aluminum nitride. The barrier layer 412 may be doped or undoped, depending on the application. In various embodiments, one or more of various other layers may be provided between the GaN layer 410 and the barrier layer 412 (i.e., the barrier layer 412 need not be directly on the GaN layer 410).

A contact layer 414 may be formed on the barrier layer 412 as illustrated in FIG. 4d. The contact layer 414 may comprise a group III-V nitride, and may be doped for achieving desired electrical properties. In some embodiments, the contact layer 414 may comprise a GaN-based material (e.g., GaN, AlGaN, InGaN, InAlN, and their quaternaries).

One or more recesses 416 may then be formed in the contact layer 414 as illustrated in FIG. 4e. The locations of the recesses 416 may be selected based at least in part on desired locations of the HFET devices to be formed. More particularly, locations of the recesses 416 may correspond to locations at which the gates for the HFET devices are to be formed, as will become more evident in the discussion to follow. The formation of the recess 416 may include one or more suitable operations including, for example, photolithographic patterning and then etching.

One or more contacts 418 may then be formed as illustrated in FIG. 4f. The contacts 418 may include, for example, source and drain contacts for facilitating functionality of the HFET device.

A gate 420 may be formed as illustrated in FIG. 4g. In some embodiments, the gate 420 may be recessed into the barrier layer 412 as illustrated but this configuration is not required. The gate 420 may instead be formed on top of the barrier layer 412 or another layer and may depend on the particular application. In some embodiments, an insulator may be disposed between the barrier layer 412 and the gate 420, forming a metal-insulator-semiconductor (MIS) structure.

Each of one or more of the nucleation layer 408, the GaN layer 410, barrier layer 412, and contact layer 414 may comprise one or more epitaxial layers. The epitaxial layer(s) may be formed by conventional epitaxial deposition techniques including, for example, molecular beam epitaxy and metal-organic chemical vapor deposition (MOCVD). Other methods may be similarly suitable.

Embodiments of devices described herein may be incorporated into various apparatuses and systems. A block diagram of an exemplary system 500 is illustrated in FIG. 5. As illustrated, the system 500 may include a power amplifier 522 and an antenna 524. The power amplifier 522 may include, among other things, a heteroepitaxial-based device 526 formed on a substrate having an off-cut angle. An exemplary device 526 may be, for example, a device such as the HFET illustrated in FIG. 1.

In various embodiments, the amplifier 522 may be configured to facilitate transmission and reception of signals, and the antenna 524 may be operatively coupled, but not necessarily directly coupled, to the amplifier 522 to transmit and receive signals.

The system 500 may be any system used for power amplification at high radio frequency power and frequency. For example, the system 500 may be suitable for any one or more of terrestrial and satellite communications, radar systems, and possibly in various industrial and medical applications. Radar applications may include military-use radar, air traffic control, navigation, and the like.

In various embodiments, the system 500 may be a selected one of a radar device, a satellite communication device, a mobile handset, or a cellular telephone base station. The system 500 may find applicability in other applications in which power amplification for high frequency transmission and/or reception is required.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. An apparatus comprising:
an off-cut substrate; and
a heteroepitaxial gallium nitride (GaN)-based device formed on the off-cut substrate.

2. The apparatus of claim 1, wherein the off-cut substrate comprises an off-cut angle of at least 0.2°.

3. The apparatus of claim 2, wherein the off-cut substrate comprises an off-cut angle of at least 0.4°.

4. The apparatus of claim 1, wherein the off-cut substrate comprises an off-cut angle of no greater than 0.7°.

5. The apparatus of claim 1, wherein the off-cut substrate is a silicon carbide substrate.

6. The apparatus of claim 1, wherein the heteroepitaxial GaN-based device includes a GaN heterojunction field effect transistor (HFET).

7. The apparatus of claim 6, wherein the GaN HFET includes a nucleation layer formed on the off-cut substrate, and a channel layer formed on the nucleation layer.

8. The apparatus of claim 6, wherein the GaN HFET includes a GaN channel layer formed on the off-cut substrate.

9. The apparatus of claim 8, wherein the GaN HFET further includes an aluminum gallium nitride barrier layer formed on the GaN channel layer.

10. A method comprising:
providing an off-cut substrate; and
forming a heteroepitaxial gallium nitride (GaN)-based device on the off-cut substrate.

11. The method of claim 10, wherein the providing of the off-cut substrate comprises providing a substrate having an off-cut angle of at least 0.2° and no greater than 0.7°.

12. The method of claim 10, wherein the providing of the off-cut substrate comprises providing a silicon carbide off-cut substrate.

13. The method of claim 10, wherein the forming of the heteroepitaxial-based device includes forming a GaN heterojunction field effect transistor (HFET).

14. The method of claim 13, wherein the forming of the GaN HFET includes forming a nucleation layer on the off-cut substrate, and forming a channel layer on the nucleation layer.

15. The method of claim 13, wherein the forming of the GaN HFET includes forming a GaN channel layer on the off-cut substrate.

16. The method of claim 15, wherein the forming of the GaN HFET further includes forming an aluminum gallium nitride barrier layer on the GaN channel layer.

17. A system comprising:
a power amplifier for amplifying a signal, the power amplifier comprising a heteroepitaxial gallium nitride (GaN)-HFET formed on an off-cut substrate; and
an antenna operatively coupled to the microelectronic device to transmit the amplified signal.

18. The system of claim 17, wherein the off-cut substrate comprises an off-cut angle of at least 0.2° and no greater than 0.7°.

19. The system of claim 17, wherein the heteroepitaxial GaN-based device is a GaN HFET.
